(19) United States
(12) Patent Application Publication
(10) Pub. No.: US 2014/0045444 A1
(43) Pub. Date: Feb. 13, 2014

(54) SIGNAL SAMPLING CIRCUIT AND RADIO RECEIVER

(71) Applicant: KABUSHIKI KAISHA TOSHIBA, Tokyo (JP)

(72) Inventors: Masanori FURUTA, Odawara-Shi (JP); Junya MATSUNO, Kawasaki-Shi (JP)

(21) Appl. No.: 13/961,786

(22) Filed: Aug. 7, 2013

(30) Foreign Application Priority Data
Aug. 10, 2012 (JP) 2012-178407

(51) Int. Cl. H03M 1/12; H04B 1/16

(52) U.S. Cl. CPC H03M 1/1245; H04B 1/16
USPC 455/230; 327/91

(57) ABSTRACT

According to some embodiments, there is provided a signal sampling circuit in which the first sampling capacitor is connected to the first sampling switch, the second sampling capacitor is connected to the second sampling switch, the amplifier outputs a positive-side amplified signal by amplifying a signal input to the positive-side input terminal thereof and outputs a negative-side amplified signal by amplifying a signal input to the negative-side input terminal thereof, the first chopper switch is connected to the first sampling capacitor and the positive-side input terminal, the second chopper switch is connected to the first sampling capacitor and the negative-side input terminal, the third chopper switch is connected to the second sampling capacitor and the positive-side input terminal and the fourth chopper switch is connected to the second sampling capacitor and the negative-side input terminal.

### CROSS REFERENCE TO RELATED APPLICATIONS

This application is based upon and claims the benefit of priority from the prior Japanese Patent Application No. 2012-178407, filed on Aug. 10, 2012, the entire contents of which are incorporated herein by reference.

### FIELD

Embodiments described herein relate to a signal sampling circuit and a radio receiver.

### BACKGROUND

A chopper-type signal sampling circuit which spreads an offset (an input-referred offset) of an amplifier that drives a sampling capacitor by spectrally spreading the offset of the amplifier, or converting the offset of the amplifier to any frequency has been proposed as a sample and hold circuit.

In the conventional circuit, a switch that reverses a polarity of an input signal is provided in addition to a switch that is used in a sampling operation of the input signal. A chopper function is thereby achieved. The circuit is a differential circuit. The switch is added in a crossing configuration such that a positive side and a negative side of a differential signal are switched with each other.

However, the conventional configuration has a problem that more power is consumed and a circuit area becomes larger since the added switch is large in size. A resistance value of the switch in an ON state causes the problem. Distortion in an A/D converter strongly depends on ON resistance of a sampling switch. Generally, a large switch is used to reduce the ON resistance. In the conventional configuration, a large switch needs to be used as the chopper switch so as to reduce the ON resistance since the chopper switch also functions as the sampling switch.

The problem becomes particularly noticeable in a time interleaved A/D converter and a successive approximation resister A/D converter in which a sampling time is shorter than a holding time.

### BRIEF DESCRIPTION OF THE DRAWINGS

FIG. 1 is a diagram showing a chopper-type signal sampling circuit according to one embodiment;

FIG. 2 is a detailed configuration diagram of an amplifier in the circuit in FIG. 1;

FIG. 3 are views showing a timing chart in FIG. 1;

FIG. 4 is a diagram showing a configuration in which an analog demodulating circuit for a chopper signal is added to the circuit in FIG. 1;

FIG. 5 are views showing a spectrum at three nodes (a Node A, a Node B, and a Node C) in the circuit in FIG. 4;

FIG. 6 is a diagram showing a configuration in which a circuit that demodulates a chopper signal in a digital domain is added to the circuit in FIG. 1;

FIG. 7 is a diagram showing an example of a polarity converting circuit;

FIG. 8 is a diagram showing one example of a chopper-type signal sampling circuit having a resetting function;

FIG. 9 is a diagram showing a specific configuration example of the circuit in FIG. 8;

FIG. 10 are views showing a timing chart of the circuit in FIG. 8;

FIG. 11 are graphs for explaining an effect of a resetting operation;

FIG. 12 is a diagram showing another example of the chopper-type signal sampling circuit having the resetting function; and

FIG. 13 is a diagram showing an example of a radio receiver.

### DETAILED DESCRIPTION

According to some embodiments, there is provided a signal sampling circuit comprising: a first sampling switch, a second sampling switch, a first sampling capacitor, a second sampling capacitor, an amplifier, a first chopper switch, a second chopper switch, a third chopper switch and a fourth chopper switch.

The first sampling switch receives a positive-side analog signal at one end.

The second sampling switch receives a negative-side analog signal at one end.

The first sampling capacitor is connected to another end of the first sampling switch at one end, and to a fixed voltage at another end.

The second sampling capacitor is connected to another end of the second sampling switch at one end, and to the fixed voltage at another end.

The amplifier includes a positive-side input terminal and a negative-side input terminal, and outputs a positive-side amplified signal by amplifying a signal input to the positive-side input terminal, and outputs a negative-side amplified signal by amplifying a signal input to the negative-side input terminal.

The first chopper switch is connected to the one end of the first sampling capacitor at one end, and to the positive-side input terminal at another end.

The second chopper switch is connected to the one end of the first sampling capacitor at one end, and to the negative-side input terminal at another end.

The third chopper switch is connected to the one end of the second sampling capacitor at one end, and to the positive-side input terminal at another end.

The fourth chopper switch is connected to the one end of the second sampling capacitor at one end, and to the negative-side input terminal at another end.

Hereinafter, embodiments will be described with accompany drawings

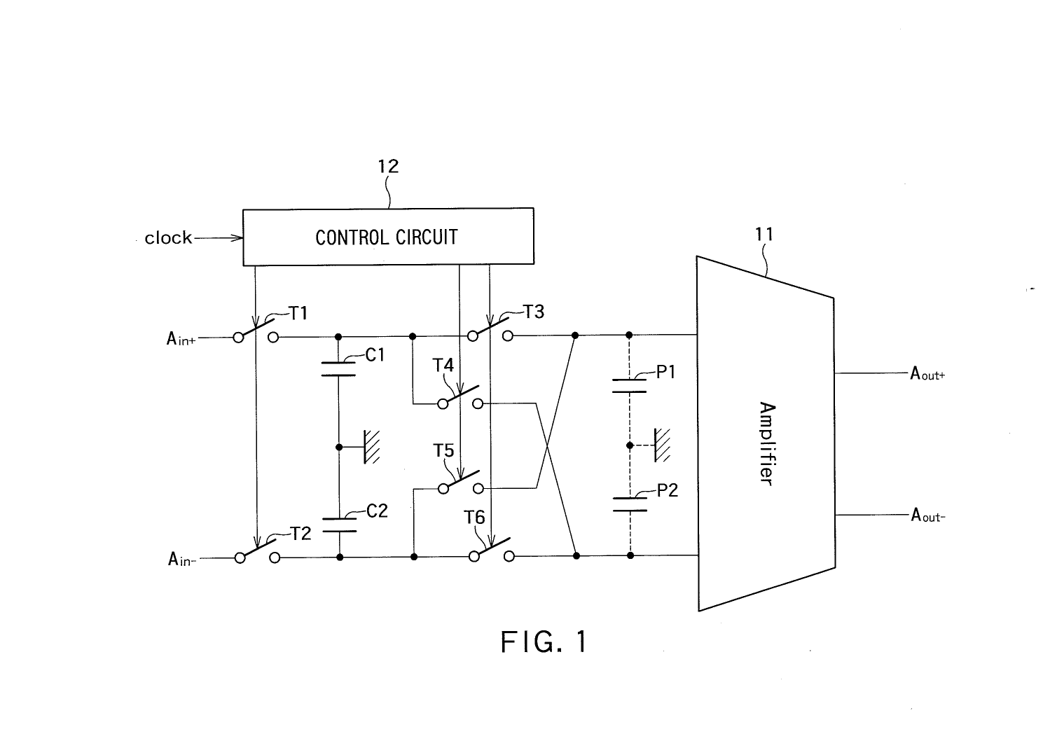

FIG. 1 shows a chopper-type signal sampling circuit according to a present embodiment.

The chopper-type signal sampling circuit according to the present embodiment is featured in converting a polarity during a holding operation in a sampling system in which a holding time is longer than a sampling time. A chopper operation of a switch is performed during the holding operation, not during a sampling operation. To be more specific, a switch for a chopper operation is provided not on an input side, but on an output side (an amplifier side) of a capacitor that samples an analog input signal. Thus, a small switch can be used as the chopper switch. A circuit area can be thereby made smaller. In the following, the present embodiment will be described in more detail.

The chopper-type signal sampling circuit shown in FIG. 1 includes sampling switches T1 and T2 as first and second sampling switches, two sampling capacitors C1 and C2 as first and second sampling capacitors, chopper switches T3, T4, T5, and T6 as first to fourth chopper switches, an amplifier 11, and a control circuit 12. Reference characters P1 and P2 denote parasitic capacitances that exist on an input side of the amplifier.

A positive-side analog input signal is input to one end of the sampling switch T1. A negative-side analog input signal is input to one end of the sampling switch T2. The positive-side analog input signal and the negative-side analog input signal constitute a differential signal.

One end of the sampling capacitor C1 is connected to the other end of the sampling switch T1. The other end of the sampling capacitor C1 is connected to a ground. The ground may be an AC ground. The ground is one example of any fixed voltage. One end of the sampling capacitor C2 is connected to the other end of the sampling switch T2. The other end of the sampling capacitor C2 is connected to the ground.

The other end of the sampling switch T1 is also connected to inputs of the chopper switches T3 and T4. The other end of the sampling switch T2 is connected to inputs of the chopper switches T5 and T6.

Outputs of the chopper switches T3 and T5 are connected to each other, and also connected to a positive-side input terminal of the amplifier. Outputs of the chopper switches T4 and T6 are connected to each other, and also connected to a negative-side input terminal of the amplifier 11.

The control circuit 12 operates according to a clock input from outside. The control circuit 12 controls the sampling switches T1 and T2 to be switched together between ON and OFF states. That is, the control circuit 12 generates a sampling switch control signal that turns ON the sampling switches T1 and T2 at the same time in each sampling cycle. The sampling switch control signal that turns ON the sampling switches T1 and T2 is, for example, at high level (“1”). The sampling switches T1 and T2 are driven according to the sampling switch control signal indicating ON, and thereby respectively turned ON.

The control circuit 12 generates a sampling switch control signal that turns OFF the sampling switches T1 and T2 at the same time after passage of a sampling operation period. The sampling switch control signal that turns OFF the sampling switches T1 and T2 is, for example, at low level (“0”). The sampling switches T1 and T2 are driven according to the sampling switch control signal indicating OFF, and thereby respectively turned OFF. A period in which the sampling switch control signal is at high level (“1”) corresponds to a sampling period. A period in which the sampling switch control signal is “0” corresponds to a holding period.

The control circuit 12 also controls the chopper switches T3 and T6 to be switched together between ON and OFF states, and the chopper switches T4 and T5 to be switched together between ON and OFF states periodically or at a predetermined timing. In this operation, the chopper switches T3 and T6, and the chopper switches T4 and T5 are operated in a complementary manner. That is, when one of the sets is ON, the other of the sets is OFF.

To be more specific, the control circuit 12 includes a random signal generator. The control circuit 12 uses the random signal generator to generate two chopper switch control signals: a first chopper switch control signal that controls the chopper switches T3 and T6, and a second chopper switch control signal that controls the chopper switches T4 and T5.

The two chopper switch control signals are in a complementary relationship. When the first chopper switch control signal indicates ON (“1”), the second chopper switch control signal indicates OFF (“0”). When the first chopper switch control signal indicates OFF, the second chopper switch control signal indicates ON.

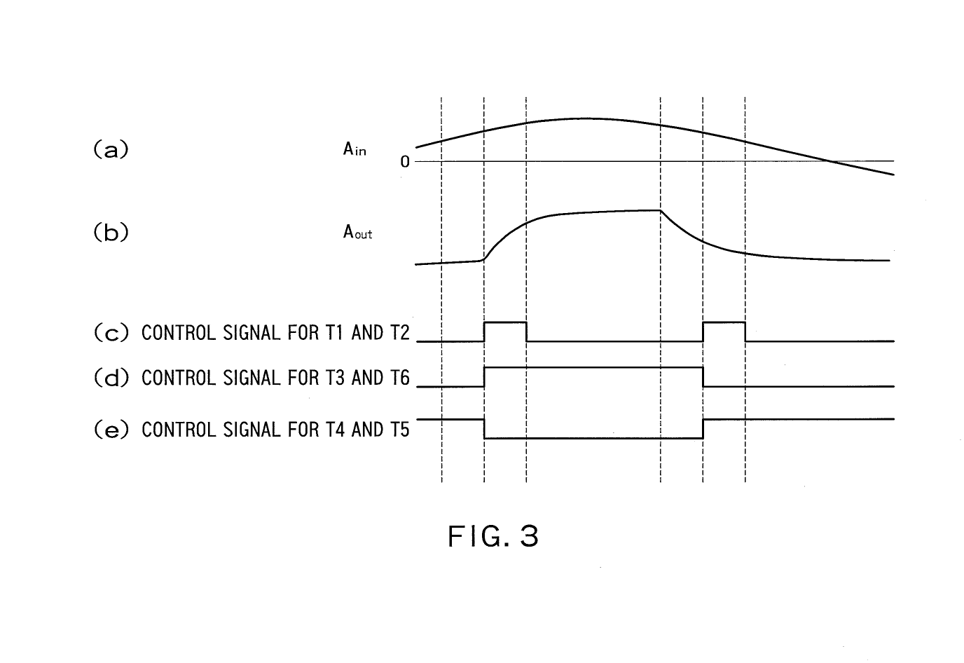

Polarities of the chopper switch control signals are randomly changed periodically or at a predetermined timing. A configuration in which the polarities are changed at a timing when the sampling switch control signal indicates ON (see FIG. 3), or a configuration in which the polarities are changed at a timing when the sampling switch control signal indicates OFF can be provided. Alternatively, the polarities may be changed after passage of a certain time period from the timing when the sampling switch control signal indicates ON (before a timing when the sampling switch control signal indicates OFF).

FIG. 3 show a timing chart of the circuit shown in FIG. 1.

FIG. 3(A) shows an analog input signal Aᵢₙ, FIG. 3(B) an output signal Aₒᵤₜ, FIG. 3(C) a control signal for the sampling switches T1 and T2 (the sampling switch control signal), FIG. 3(D) a control signal for the chopper switches T3 and T6 (the first chopper switch control signal), and FIG. 3(E) a control signal for the chopper switches T4 and T5 (the second chopper switch control signal). The analog input signal Aᵢₙ means a differential between Aᵢₙ₊ and Aᵢₙ₋ (Aᵢₙ=Aᵢₙ₊−Aᵢₙ₋) in FIG. 1. The output signal Aₒᵤₜ means a differential between Aₒᵤₜ₊ and Aₒᵤₜ₋.

As described above, the sampling in the circuit is performed during the period in which the sampling switch control signal is “1”. The period in which the sampling switch control signal is “0” is entirely the holding period.

The first chopper switch control signal and the second chopper switch control signal are generated with different polarities from each other as described above. The respective polarities are randomly determined. In the preset embodiment, the first chopper switch control signal and the second chopper switch control signal are generated in synchronization with a positive-side edge (a rising edge) of the sampling switch control signal. The first chopper switch control signal and the second chopper switch control signal are in a complementary relationship. Thus, the first chopper switch control signal and the second chopper switch control signal do not become “1” at the same time, nor become “0” at the same time.

There is a period in which the sampling switch control signal becomes “1” at the same time as the first or second chopper switch control signal. This is to reduce influences of the parasitic capacitances P1 and P2 (see FIG. 1). For example, if the sampling switch control signal and the first or second chopper switch control signal do not become “1” at the same time (a non-overlap clock), only the sampling switch control signal assumes the ON state during the sampling period. Thus, the signal sampling is performed only in the sampling capacitors C1 and C2. In the holding period, the sampling switch control signal assumes the OFF state, and the first or second chopper switch control signal assumes the ON state. Thus, the sampling capacitors C1 and C2, and the parasitic capacitances P1 and P2 are connected in parallel. Accordingly, signal charge accumulated in the sampling capacitors C1 and C2 is redistributed between the sampling capacitors C1 and C2 and the parasitic capacitances P1 and P2. The signal charge is unnecessarily added or subtracted. Distortion is thereby caused.

Meanwhile, in the present circuit, there is a period in which the sampling switch control signal and the first or second chopper switch control signal assume the ON states at the same time during the sampling operation. Thus, the signal sampling is performed not only in the sampling capacitors C1 and C2, but also in the parasitic capacitances P1 and P2. The problem of charge redistribution is thus eliminated or reduced. In general, the parasitic capacitances P1 and P2 are sufficiently smaller than the sampling capacitors C1 and C2, so that there is a smaller demand for a reduction in an ON resistance value of the chopper switch. Since the chopper operation is performed during the holding time that is longer than the sampling time, a chopper operation period can be extended. Consequently, a small switch can be used as the chopper switches T3, T4, T5, and T6 that are used for converting the polarity.

In the period in which the sampling switch control signal is “1”, charge is accumulated in the sampling capacitors C1 and C2. In the period in which the sampling switch control signal is “0”, the charge is held (signal holding). The charge is held in the capacitors C1 and C2 until a next sampling switch control signal becomes “1”. The charge (or voltage) accumulated in the sampling capacitors is normally used to drive a load (not shown) outside the chopper-type sampling circuit. The amplifier 11 is used as a driving circuit for the held voltage. Amplification gain of the amplifier 11 may be determined based on a circuit downstream thereof. The amplification gain may be set to, for example, one.

Here, the charge accumulated in the positive-side sampling capacitor C1 is input to the positive-side input terminal of the amplifier 11 when the chopper switch T3 is ON and the chopper switch T4 is OFF. The charge is input to the negative-side input terminal of the amplifier 11 when the chopper switch T3 is OFF and the chopper switch T4 is ON. Similarly, the charge accumulated in the negative-side sampling capacitor C2 is input to the negative-side input terminal of the amplifier 11 when the chopper switch T6 is ON and the chopper switch T5 is OFF. The charge is input to the positive-side input terminal of the amplifier 11 when the chopper switch T6 is OFF and the chopper switch T5 is ON. In this manner, the polarity input to the amplifier 11 from each of the sampling capacitors is changed depending on the first and second chopper switch control signals whose polarities are randomly changed (the chopper operation). The amplifier 11 amplifies the signal input to the positive-side input terminal, and outputs an amplified positive-side signal from a positive-side output terminal (a first positive-side output terminal). The amplifier 11 also amplifies the signal input to the negative-side input terminal (a first negative-side output terminal), and outputs an amplified negative-side signal from a negative-side output terminal.

The rising edges of the sampling switch control signal and the first or second chopper switch control signal correspond to (or coincide with) each other in the example in FIG. 3; however, the rising edges do not always need to correspond to each other as long as there is a period in which the sampling switch control signal and the first or second chopper switch control signal assume the ON states at the same time during the sampling operation period. The first or second chopper switch control signal may not completely cover the ON period of the sampling switch control signal. It is not an indispensable condition in the present embodiment that there is a period in which the sampling switch control signal and the first or second chopper switch control signal assume the ON states at the same time during the sampling operation period. An effect of the present embodiments described below (an effect of reducing the circuit area) can be obtained even in this case.

The signal sampling time in the parasitic capacitances P1 and P2 is determined by a time constant obtained by the ON resistance of the chopper switches T3, T4, T5, and T6, and a parasitic capacitance value. Thus, a falling edge of the sampling switch control signal needs to overlap with the ON period of the first or second chopper switch control signal. An overlapping time thereof also needs to be equal to or longer than the time constant.

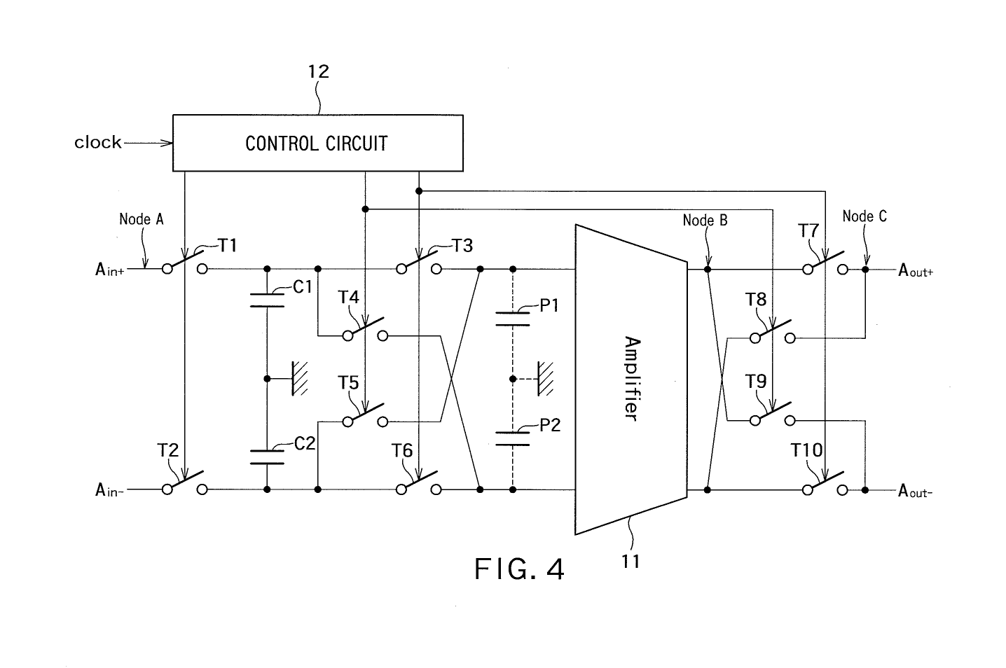

When the input analog signal is chopped by the chopper switches T3, T4, T5, and T6 as described above, the signal is spectrally spread. The spectrally-spread signal is input to the amplifier 11. A demodulating circuit (see FIG. 4) is provided downstream of the amplifier 11. The demodulating circuit demodulates the spectrally-spread signal. The demodulated signal is A/D-converted to obtain a digital code.

FIG. 4 shows a configuration in which the demodulating circuit is provided downstream of the chopper-type signal sampling circuit shown in FIG. 1.

A configuration in which the demodulating circuit is achieved by an analog circuit is shown in FIG. 4. The demodulating circuit includes four switches T7, T8, T9, and T10 as fifth to eighth chopper switches. The first chopper switch control signal is input to the switches T7 and T10 similarly to the chopper switches T3 and T6. The second chopper switch control signal is input to the switches T8 and T9 similarly to the chopper switches T4 and T5. The switches T7, T8, T9, and T10 are controlled as described above. Accordingly, the polarity of the signal is converted on the demodulating circuit side when the polarity is converted on the input side of the amplifier 11 by the chopper operation. The polarity of the signal is not converted on the demodulating circuit side when the polarity is not converted on the input side of the amplifier 11 by the chopper operation. An A/D converter is arranged downstream of the demodulating circuit to A/D-convert the demodulated signal. The digital code can be thereby obtained.

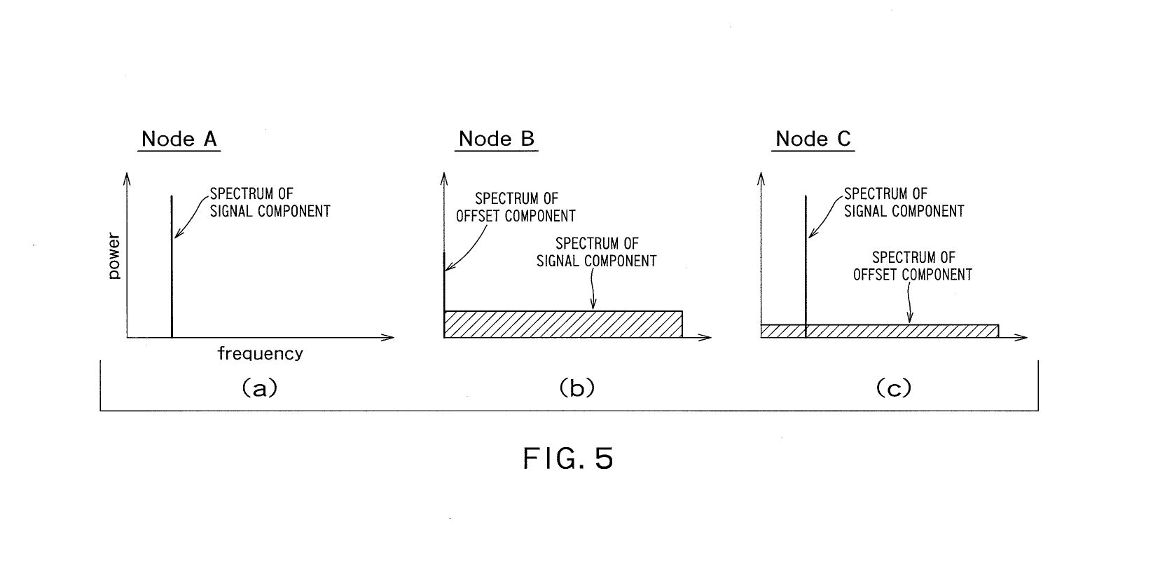

FIG. 5 show one example of a signal spectrum at each of an input node A, an amplifier output node B, and an output node C in FIG. 4. FIG. 5(A) shows the signal spectrum at the input node A, FIG. 5(B) the signal spectrum at the amplifier output node B, and FIG. 5(C) the signal spectrum at the output node C. Incidentally, the output node C corresponds to a second positive-side output terminal and the corresponding node in the opposite polarity side corresponds to a second negative-side output terminal.

As shown in FIG. 5(A), it is assumed that a single sine wave is input as the input signal.

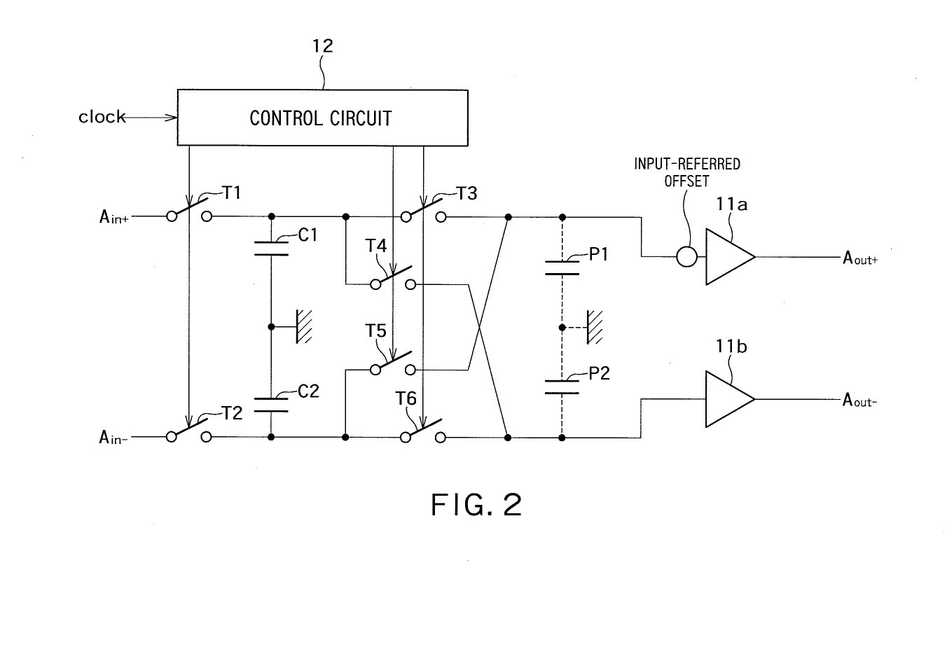

As shown in FIG. 5(B), since the input signal is spectrally spread by the chopper operation by the chopper switches T3 to T6, an input signal component is evenly spread over an entire frequency band at the amplifier output node B. A spectrum of an input-referred offset (a DC (direct-current) component) existing at an input of the amplifier 11 is superimposed on the signal band. The input-referred offset existing at the input of the amplifier 11 is schematically shown in FIG. 2. The amplifier 11 includes amplifiers 11a and 11b. Here, an input-referred offset of the amplifier 11a is shown. Actually, there is also an input-referred offset at the amplifier 11b. An input of the amplifier 11a is connected to the outputs of the chopper switches T3 and T5. An input of the amplifier 11b is connected to the outputs of the chopper switches T4 and T6.

As shown in FIG. 5(C), the spectrally-spread input signal is decoded to the original single sine wave by a chopper operation by the chopper switches T7 to T10 at the output node C. Meanwhile, the input-referred offset (see FIG. 5(B)) added in the amplifier 11 is spectrally spread by the chopper operation by the chopper switches T7 to T10. An offset component is thereby evenly spread over the entire frequency band. When the offset component (the DC component) is spectrally spread, it is found that the offset has been reduced to lower than an original DC component (see FIG. 5(B)) of the operational amplifier 11.

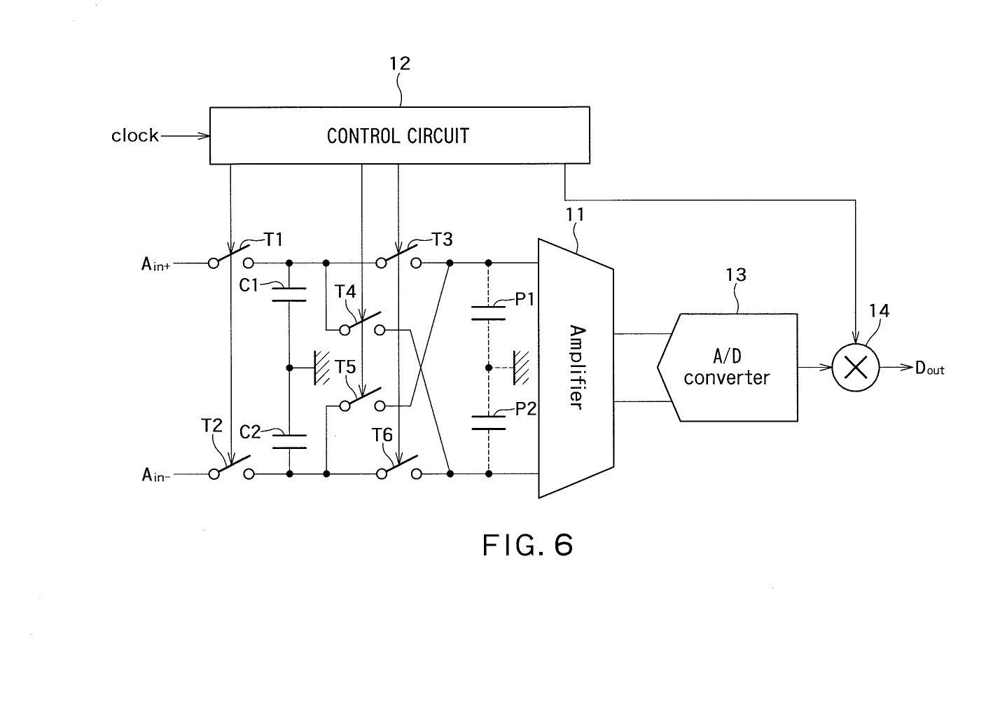

FIG. 6 shows an example in which the demodulating circuit downstream of the chopper-type signal sampling circuit is composed of a digital circuit.

Although the circuit of a basic analog portion is the same as the circuit in FIG. 1, an A/D converter 13 and a digital multiplying circuit (a polarity converting circuit) 14 are added thereto.

The A/D converter 13 A/D-converts an output signal from the amplifier 11, and generates a digital signal (a digital code). The digital multiplying circuit 14 multiplies the digital signal by a signal of 1 or −1 to control a polarity of the output signal. For example, when the chopper switches T3 and T6 are ON (“1”), the digital code output from the A/D converter 13 is multiplied by the signal of 1. When the chopper switches T4 and T5 are ON, the digital signal output from the A/D converter 13 is multiplied by the signal of −1. The polarity is thereby converted.

As described above, the input signal spectrally spread by the chopper operation by the switches T3 to T6 is demodulated in a digital domain by the digital multiplying circuit 14. The demodulating circuit can be thereby simplified. Offset components of the amplifier 11 and the A/D converter 13 can be also reduced.

As described above, in the configuration in FIG. 6, the circuit for chopper demodulation can be made smaller. The offset from the amplifier to the A/D converter can be also spectrally spread.

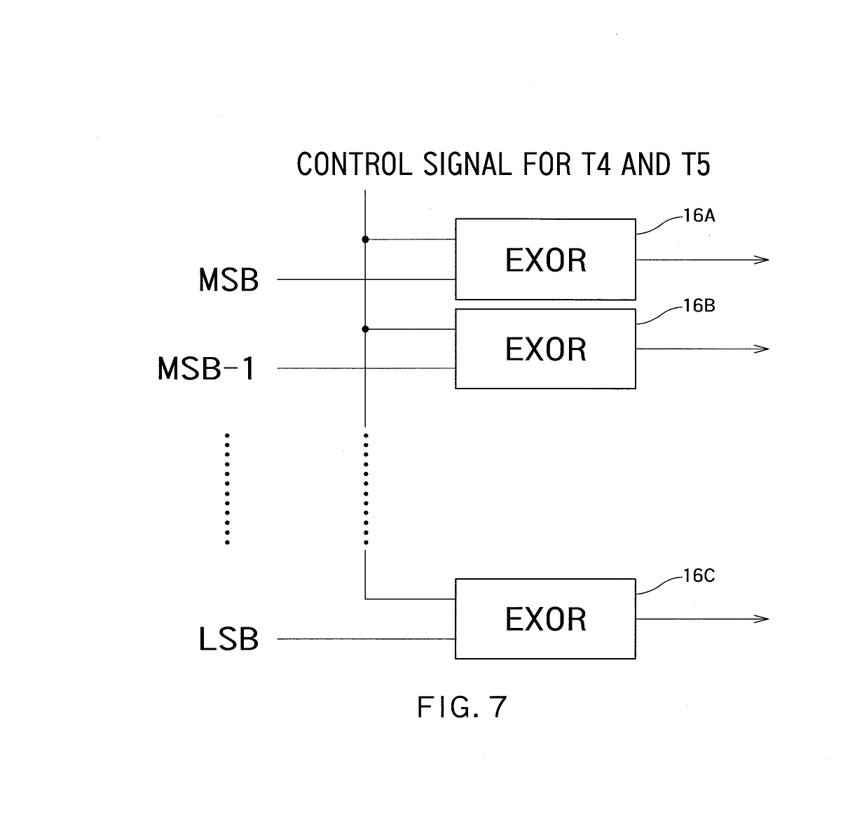

FIG. 7 shows a specific example of the digital multiplying circuit.

Depending on a scheme, the polarity reversing operation in the digital domain can be achieved by, for example, reversing each bit. Each bit in a bit string (MSB, MSB-1, MSB-2, and so on, up to LSB) obtained by one sampling operation and A/D conversion is reversed according to the control signal for T4 and T5. To be more specific, when the control signal for T4 and T5 is “0”, each bit is not reversed. When the control signal for T4 and T5 is “1”, each bit is reversed. The operation can be achieved by exclusive OR circuits (EXOR circuits) 16A, 16B, and so on, up to 16C arranged corresponding to the respective bits. A corresponding bit in the bit string is input to each of the exclusive OR circuit, and the control signal for T4 and T5 is also input thereto. In a case in which the control signal for T4 and T5 is “1”, the output is “0” when the input bit is “1”, and the output is “1” when the input bit is “0”. Thus, the bit is reversed. In a case in which the control signal for T4 and T5 is “0”, the output is “0” when the input bit is “0”, and the output is “1” when the input bit is “1”. Thus, the bit is not reversed.

Here, it is assumed that a latency required for the conversion in the A/D converter is 0. Actually, there is a latency in the A/D converter. Thus, the control signal for T4 and T5 is delayed and input. Accordingly, the MSB as an output code of the A/D converter and the control signal for T4 and T5 are input to the exclusive OR circuit in synchronization with each other. The amount of delay is adjusted in the control circuit 12 according to the latency in the A/D converter. If there is no latency in the A/D converter, it is not necessary to delay the control signal.

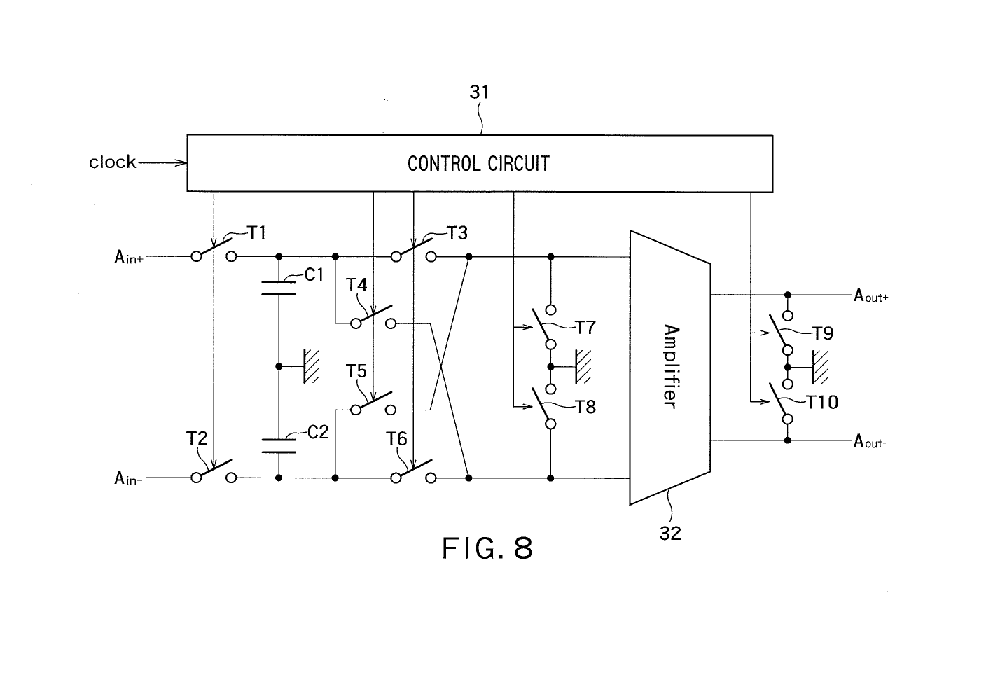

FIG. 8 shows a chopper-type signal sampling circuit according to a second embodiment.

Although the circuit is basically the same as the circuit in FIG. 1, the circuit differs therefrom in that resetting switches T7, T8, T9, and T10 are newly added as first to fourth resetting switches.

The present circuit reduces an influence of a parasitic capacitance that exists between an input and an output of an amplifier 32. If there is a parasitic capacitance between the input and the output of the amplifier, a sampling operation is affected by a voltage held on the parasitic capacitance until right before the sampling operation (a memory effect). Distortion characteristics are thereby deteriorated. To solve the problem, the resetting switches are provided in the present circuit. The influence of the memory effect can be reduced by respectively resetting the input and the output of the amplifier 32 to a ground before the sampling operation.

In the present configuration, a capacitance parasitic not only on the input side, but also on the output side of the amplifier is taken into consideration unlike in the configuration shown in FIG. 1. It is assumed that an output voltage of the amplifier cannot track an input voltage at high speed. When the amplifier output voltage cannot track the input voltage in zero time, a difference in potential is generated between the input and the output. Unnecessary charge is thereby accumulated in the parasitic capacitance. The unnecessary charge is injected into a sampling capacitor for an input signal. When the input signal has a direct current, the difference in potential is ideally always 0. Thus, the above problem does not occur. However, when a time-varying input signal is sampled, the difference in potential differs in each sampling. Thus, the charge differing each time is injected into the sampling capacitor. The deterioration in the distortion characteristics is thereby caused (a record effect). In the present configuration, the resetting switches are respectively provided at the input and the output of the amplifier so as to cancel an influence of the record effect.

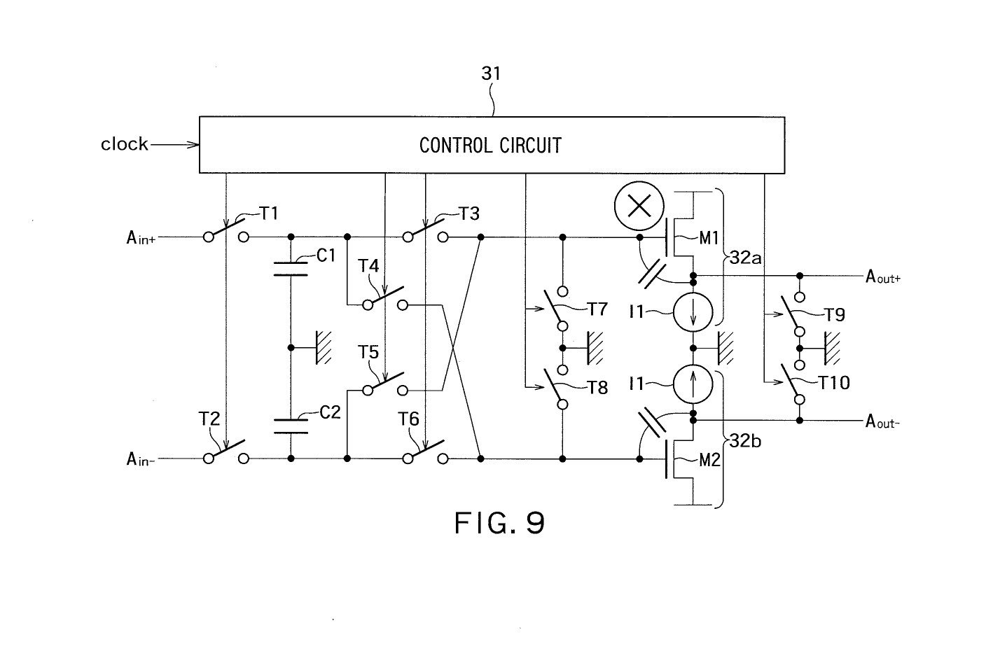

FIG. 9 shows a specific example of the circuit in FIG. 8.

The amplifier 32 is achieved by two single-phase source follower amplifiers 32a and 32b. In the case of the circuit, a parasitic capacitance exists between a gate and a source of an input transistor M1 of the source follower amplifier 32a, and between a gate and a source of an input transistor M2 of the source follower amplifier 32b.

While the sampling operation is being performed, the same voltage as the analog input signal is applied to a node X. The same voltage as the analog input is not applied to the output of the amplifier. This is because a driving capability of the amplifier is limited.

Since the output of the amplifier changes during the sampling operation, charge corresponding to a differential voltage between the input signal and an amplifier output signal is accumulated in the parasitic capacitance. Since the output of the amplifier continues to change even after termination of the sampling, charge corresponding to a changing voltage after the termination of the sampling is added to the sampling capacitors C1 and C2. An error signal is thereby generated. The error changes according to the magnitude of the change in the output of the amplifier. As a result, the deterioration in distortion performance is caused.

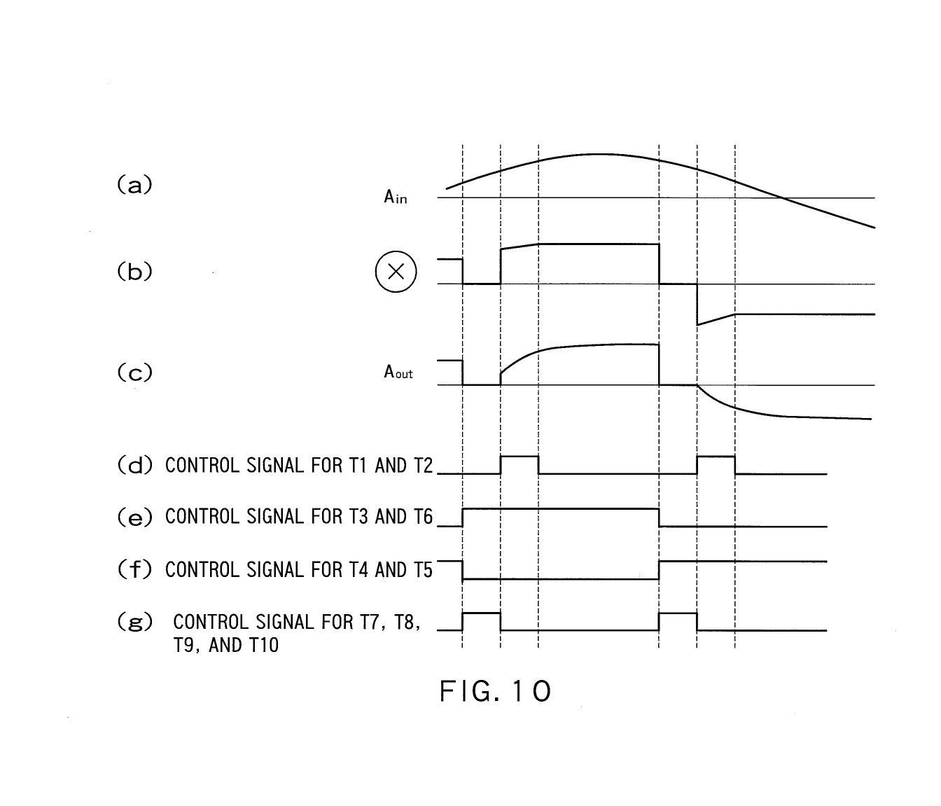

FIG. 10 show a timing chart of the present circuit. A control signal for the resetting switches T7, T8, T9, and T10 indicates ON (“1”) before the sampling switch control signal for the sampling switches T1 and T2 indicates ON (“1”). The input node and the output node of the amplifier are thereby reset once, and set to the ground (a voltage of “0”). That is, a difference in potential between the gate and the source of the input transistor is set to 0. The sampling operation is then started. The record of the charge stored in the parasitic capacitance is thereby cancelled before the sampling starts. The deterioration in the distortion characteristics can be reduced.

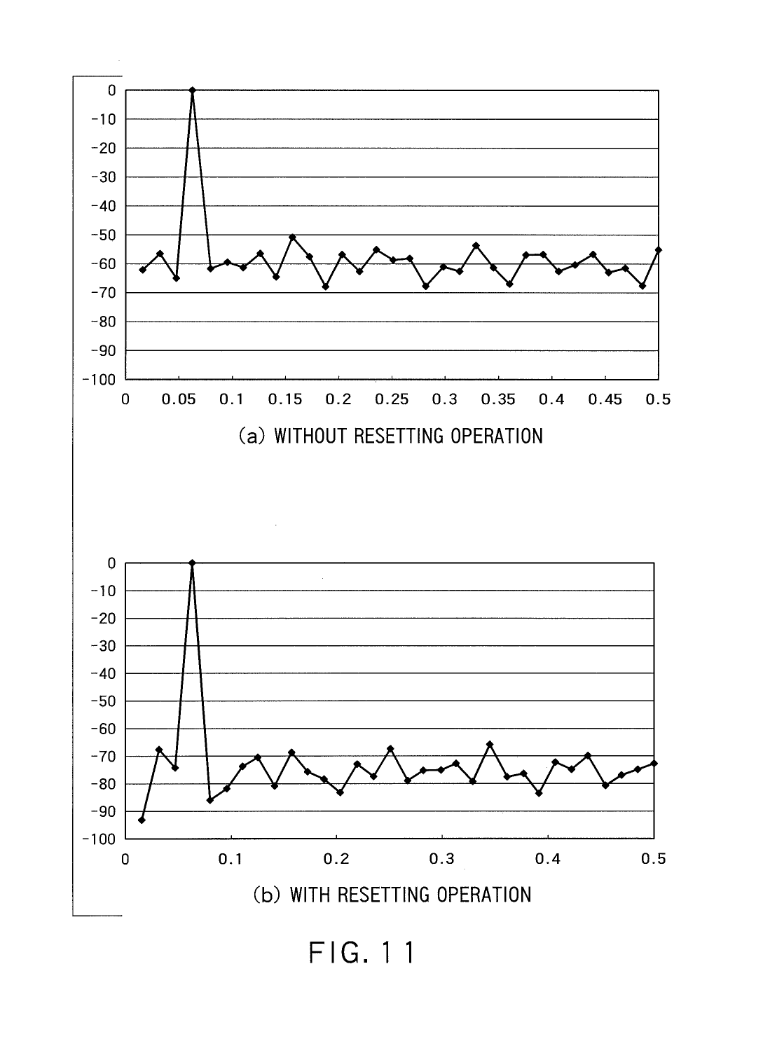

FIG. 11 show one example of a distortion improving effect by the resetting operation. An upper side in the drawings shows a case in which the resetting operation was not performed, and a lower side shows a case in which the resetting operation was performed. A vertical axis represents a power of an output Aₒᵤₜ₊. A horizontal axis represents a frequency. When an operating frequency of the circuit is represented as “FS”, a value on the horizontal axis×“FS” is the frequency shown on the horizontal axis. An SFDR (spurious-free dynamic range) obtained when the resetting operation was performed was 52.37, and when the resetting operation was not performed was 67.22. Therefore, in the example, a harmonic can be improved by about 15 DB by the resetting operation. That is, the distortion can be reduced.

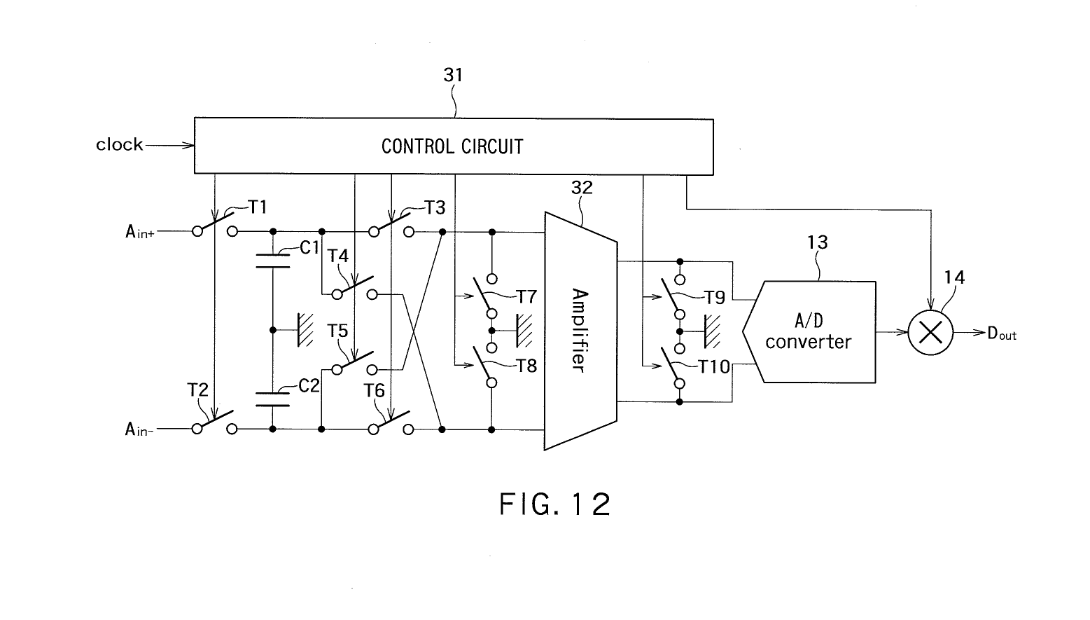

FIG. 12 shows a circuit in which a digital demodulating circuit is arranged downstream of the circuit in FIG. 8.

The digital demodulating circuit includes an A/D converter 13 and a digital multiplier 14. Since a configuration and an operation of the digital demodulating circuit are the same as those in FIG. 6, the description thereof is omitted.

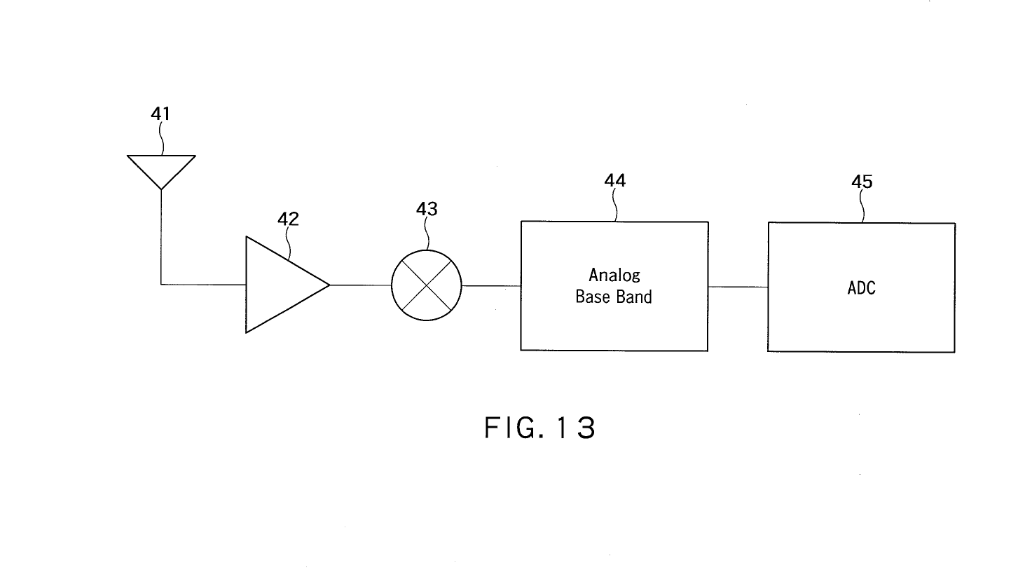

FIG. 13 shows a radio receiver according to one embodiment.

The radio receiver includes an antenna 41, an LNA 42, a mixer 43, an analog baseband circuit 44, and an A/D converter circuit 45. The A/D converter circuit 45 includes the chopper-type signal sampling circuit and the A/D converter described above. The A/D converter circuit 45 may be a successive approximation resister A/D converter circuit (SAR ADC).

A radio signal received at the antenna 41 is amplified by the LNA (low noise amplifier) 42. The radio frequency signal amplified by the LNA 42 is down-converted to a baseband signal by the mixer 43. The baseband signal is filtered by the analog baseband circuit 44 to obtain a signal in a desired band. The filtered analog signal is converted to a digital signal by the A/D converter circuit 45.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A signal sampling circuit comprising:
a first sampling switch to receive a positive-side analog signal at one end;
a second sampling switch to receive a negative-side analog signal at one end;
a first sampling capacitor connected to another end of the first sampling switch at one end, and to a fixed voltage at another end;
a second sampling capacitor connected to another end of the second sampling switch at one end, and to the fixed voltage at another end;
an amplifier including a positive-side input terminal and a negative-side input terminal, and configured to output a positive-side amplified signal by amplifying a signal input to the positive-side input terminal, and output a negative-side amplified signal by amplifying a signal input to the negative-side input terminal;
a first chopper switch connected to the one end of the first sampling capacitor at one end, and to the positive-side input terminal at another end;
a second chopper switch connected to the one end of the first sampling capacitor at one end, and to the negative-side input terminal at another end;
a third chopper switch connected to the one end of the second sampling capacitor at one end, and to the positive-side input terminal at another end; and
a fourth chopper switch connected to the one end of the second sampling capacitor at one end, and to the negative-side input terminal at another end.

2. The signal sampling circuit according to claim 1, wherein
the first and second sampling switches are controlled to be switched together between On and OFF states,
the first and fourth chopper switches are controlled to be switched together between On and OFF states,
the second and third chopper switches are controlled to be switched together between On and OFF states,
the first and fourth chopper switches operate in a complementary manner to the second and third chopper switches, and
all or a portion of a period in which the first and second sampling switches are ON overlaps with a period in which the first and fourth chopper switches are ON, or a period in which the second and third chopper switches are ON.

3. The signal sampling circuit according to claim 1, wherein
the amplifier includes a first positive-side output terminal to output the positive-side amplified signal, and a first negative-side output terminal to output the negative-side amplified signal,
the signal sampling circuit further comprising:
a fifth chopper switch connected to the first positive-side output terminal at one end;
a sixth chopper switch connected to the first negative-side output terminal at one end;
a seventh chopper switch connected to the first positive-side output terminal at one end;
an eighth chopper switch connected to the first negative-side output terminal at one end;
a second positive-side output terminal connected to another end of the fifth chopper switch and another end of the sixth chopper switch; and
a second negative-side output terminal connected to another end of the seventh chopper switch and another end of the eighth chopper switch.

4. The signal sampling circuit according to claim 1, wherein
the amplifier includes a first positive-side output terminal to output the positive-side amplified signal, and a first negative-side output terminal configured to output the negative-side amplified signal,
the signal sampling circuit further comprising:
a first resetting switch connected to the first positive-side input terminal at one end, and to the fixed voltage at another end;
a second resetting switch connected to the first negative-side input terminal at one end, and to the fixed voltage at another end;
a third resetting switch connected to the first positive-side output terminal at one end, and to the fixed voltage at another end;
a fourth resetting switch connected to the first negative-side output terminal at one end, and to the fixed voltage at another end; and
a control circuit to control the first to fourth resetting switches to be turned ON before the first and second sampling switches are turned ON.

5. The signal sampling circuit according to claim 1, further comprising:
an A/D converter configured to generate a digital code by performing A/D conversion based on the positive-side amplified signal and the negative-side amplified signal,
a control circuit configured to generate a first control signal that controls the first and fourth chopper switches, and a second control signal that controls the second and third chopper switches; and
a polarity converting circuit configured to control a polarity of the digital code based on at least one of the first control signal and the second control signal.

6. The signal sampling circuit according to claim 5, wherein
the polarity converting circuit reverses a polarity of the
digital code when the first control signal indicates OFF, or the second control signal indicates ON.

7. A radio receiver comprising:
an antenna to receive a radio signal;
an amplifier to amplify the radio signal received at the antenna;
a mixer to convert the signal amplified by the amplifier to a baseband signal;
an analog baseband section configured to filter the baseband signal; and
an A/D converter section including a signal sampling circuit according to claim 1 to sample the filtered signal.
